(19) United States
(12) Patent Application Publication
(10) Pub. No.: US 2013/0320463 A1
(43) Pub. Date: Dec. 5, 2013

(54) PACKAGE STRUCTURE HAVING MEMS ELEMENT AND FABRICATION METHOD THEREOF

(71) Applicants: Hong-Da Chang, Taichung Hsien (TW); Cheng-Hsiang Liu, Taichung Hsien (TW); Kuang-Wei Huang, Taichung Hsien (TW); Chun-Hung Lin, Taichung Hsien (TW); Hsin-Yi Liao, Taichung Hsien (TW)

(72) Inventors: Hong-Da Chang, Taichung Hsien (TW); Cheng-Hsiang Liu, Taichung Hsien (TW); Kuang-Wei Huang, Taichung Hsien (TW); Chun-Hung Lin, Taichung Hsien (TW); Hsin-Yi Liao, Taichung Hsien (TW)

(73) Assignee: SILICONWARE PRECISION INDUSTRIES CO., LTD., Taichung Hsien (TW)

(21) Appl. No.: 13/588,113

(22) Filed: Aug. 17, 2012

(30) Foreign Application Priority Data
May 29, 2012 (TW) 101119074

(51) Int. Cl. H01L 29/84; H01L 21/60

(52) U.S. Cl. 257/415; 438/51; 257/E29.324; 257/E21.506

(57) ABSTRACT

A package structure includes: a substrate having a plurality of first conductive pads and a plurality of second conductive pads; an MEMS element disposed on the substrate; a cover member disposed on the MEMS element and having a metal layer formed thereon; a plurality of bonding wires electrically connected to the MEMS element and the second conductive pads of the substrate; a plurality of first wire segments, each having one end electrically connected to a corresponding one of the first conductive pads; and an encapsulant formed on the substrate and encapsulating the MEMS element, the cover member, the first wire segments and the bonding wires, wherein the other end of each of the first wire segments is exposed from the encapsulant. Compared with the prior art, the package structure of the present invention has improved overall yield and functionality.

### BACKGROUND OF THE INVENTION

1. Field of the Invention

The present invention relates to package structures and fabrication methods thereof, and, more particularly, to a package structure having a micro-electro-mechanical system (MEMS) element and a fabrication method thereof.

2. Description of Related Art

MEMS elements have electrical and mechanical functions integrated therein and can be fabricated through various micro-fabrication technologies.

FIGS. 1A to 1C are schematic cross-sectional views showing a conventional package structure having MEMS elements and a fabrication method thereof.

Referring to FIG. 1A, a substrate 10 having a plurality of MEMS elements 101 arranged in an array is provided. Each of the MEMS elements 101 has a cover member 11 disposed thereon. An application specific integrated circuit (ASIC) chip 12 is further disposed on the cover member 11 and electrically connected to the MEMS element 101 and the cover member 11 through bonding wires.

Referring to FIG. 1B, an encapsulant 13 is formed on the substrate 10 and encapsulates the cover members 11 and the ASIC chips 12.

Referring to FIG. 1C, a singulation process is performed to obtain a plurality of semiconductor packages.

However, since no test is performed to identify known good dies (KGD) of the MEMS elements 101 before the ASIC chips 12 are disposed on the MEMS elements 101, the yield of the final package structure is adversely affected. Further, the above-described package structure and fabrication method are applicable only if the ASIC chips 12 are smaller in size than the MEMS elements 101.

Therefore, there is a need to provide a package structure and a fabrication method thereof so as to overcome the above-described drawbacks.

### SUMMARY OF THE INVENTION

Accordingly, the present invention provides a package structure, comprising: a substrate having a first surface and a second surface opposite to the first surface, a plurality of first conductive pads and a plurality of second conductive pads disposed on the first surface; a first MEMS element disposed on the first surface of the substrate; a first cover member disposed on the first MEMS element and having a metal layer formed on a top surface thereof; a plurality of bonding wires electrically connected to the first MEMS element and the second conductive pads; a plurality of first wire segments, each having one end electrically connected to a corresponding one of the first conductive pads; and an encapsulant formed on the substrate and encapsulating the first MEMS element, the first cover member, the first wire segments and the bonding wires, wherein the other end of each of the first wire segments is exposed from the encapsulant.

The present invention further provides a fabrication method of a package structure, comprising the steps of: providing a substrate having a first surface and a second surface opposite to the first surface, with a plurality of first conductive pads and a plurality of second conductive pads disposed on the first surface; disposing a first MEMS element on the first surface of the substrate, wherein the first MEMS element has a first cover member disposed thereon and a metal layer is formed on a top surface of the first cover member; electrically connecting the metal layer and the first conductive pads through a plurality of first bonding wires, and electrically connecting the first MEMS element and the second conductive pads through a plurality of second bonding wires; forming on the substrate an encapsulant that encapsulates the first MEMS element, the first cover member, the first bonding wires and the second bonding wires; and partially removing the encapsulant from a top surface thereof so as to separate the first bonding wires into a plurality of first wire segments with one ends electrically connecting to the first conductive pads and the other ends exposed from the top surface of the encapsulant.

Since singulated MEMS elements are used in the present invention, known good dies (KGD) can be selected so as to increase the yield of the package structure. Further, by forming alignment keys on a bottom surface of the substrate, a double side aligner can be conveniently used for alignment during the fabrication process. Furthermore, the present invention is applicable to the case in which the MEMS element is smaller in size than the substrate. In addition, a plurality of MEMS elements can be integrated in a same package structure so as to increase the overall functionality.

### BRIEF DESCRIPTION OF DRAWINGS

FIGS. 1A to 1C are schematic cross-sectional views showing a conventional package structure having MEMS elements and a fabrication method thereof;

FIGS. 2A to 2G are schematic cross-sectional views showing a package structure having MEMS elements and a fabrication method thereof according to a first embodiment of the present invention; and

FIGS. 3A and 3B are schematic cross-sectional views showing a package structure having MEMS elements according to a second embodiment of the present invention.

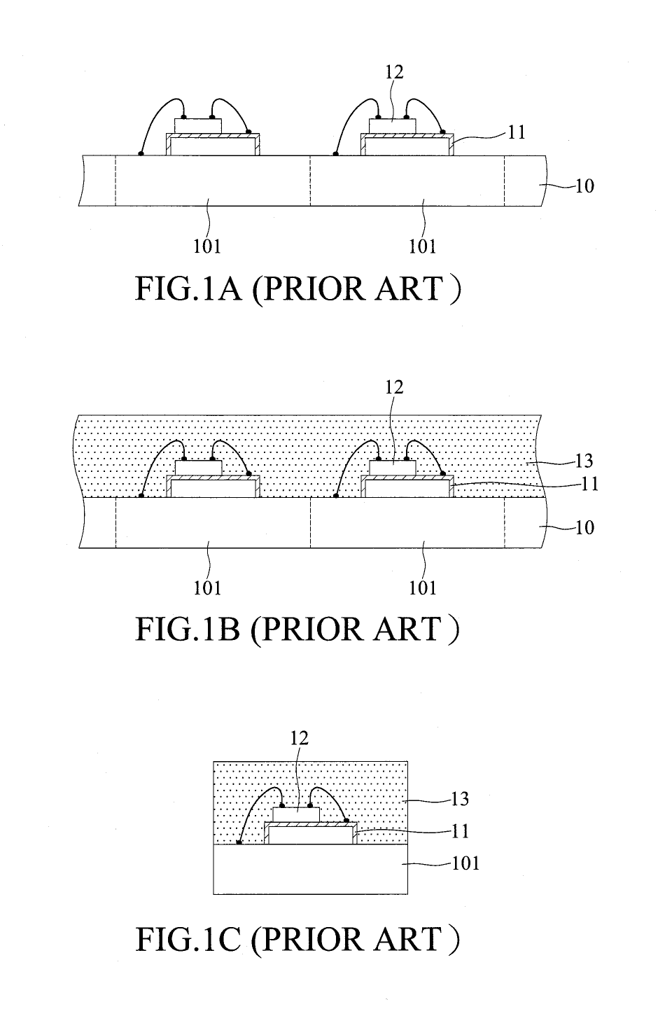

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “top”, “bottom”, “on”, “a” etc. are merely for illustrative purpose and should not be construed to limit the scope of the present invention.

### FIRST EMBODIMENT

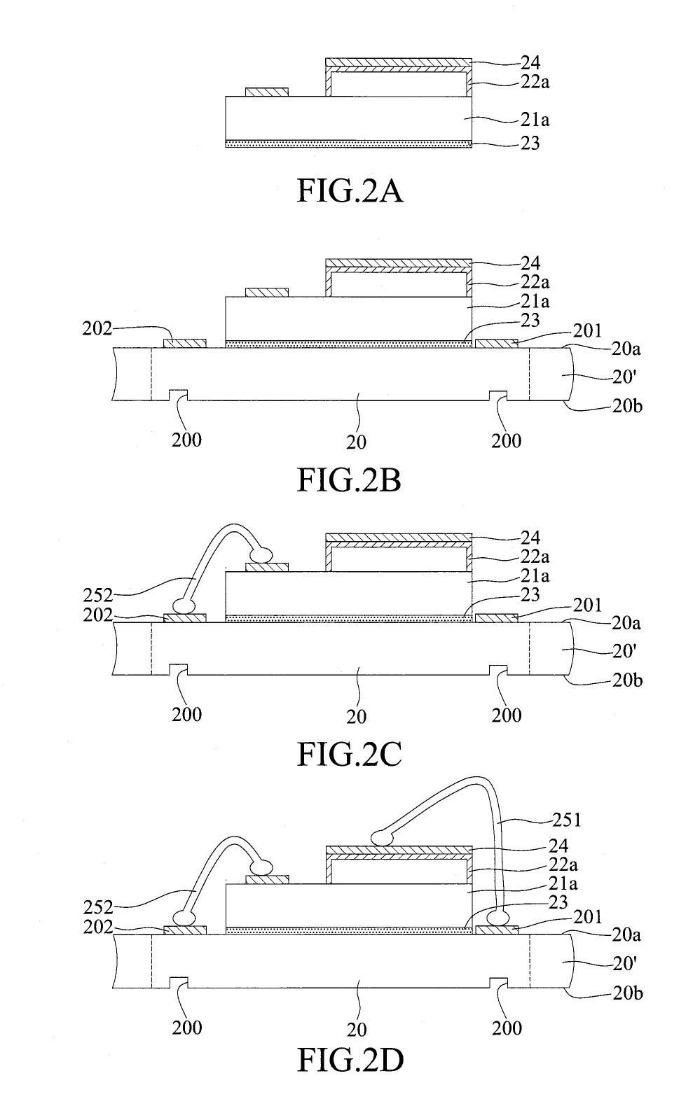

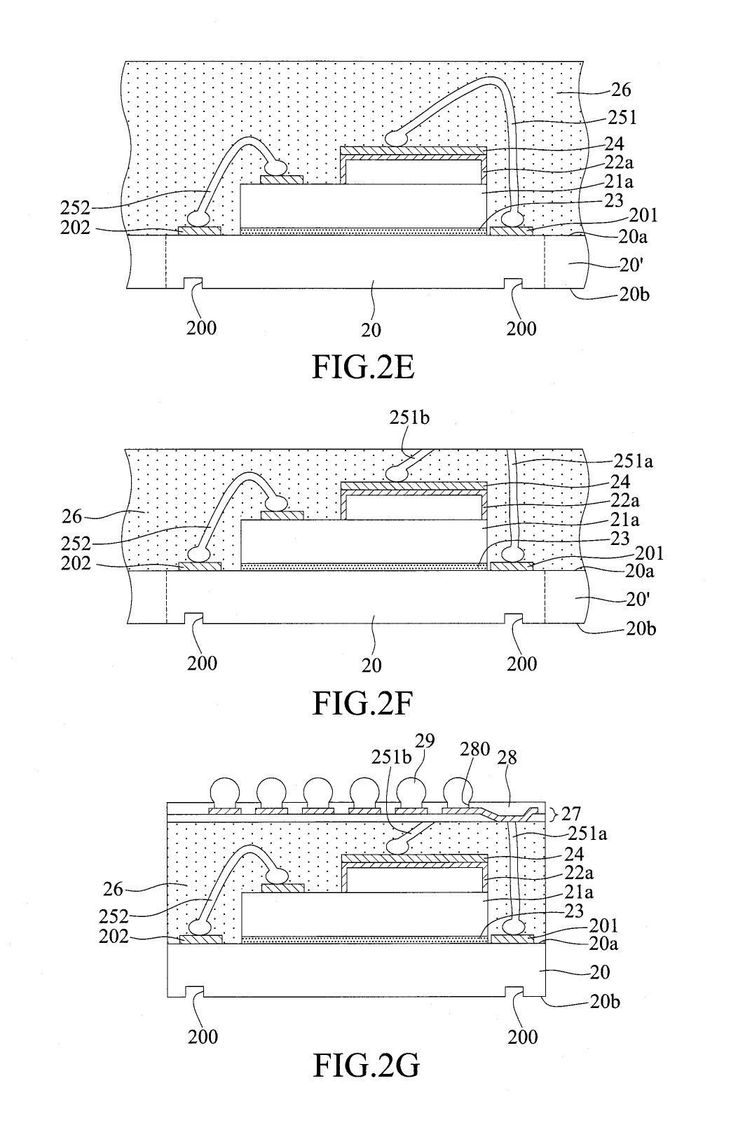

FIGS. 2A to 2G are schematic cross-sectional views showing a package structure having an MEMS element and a fabrication method thereof according to a first embodiment of the present invention.

Referring to FIG. 2A, a first MEMS element 21a is provided, which has a first cover member 22a disposed on a top surface thereof and an adhesive layer 23 formed on a bottom surface thereof. Further, a metal layer 24 is formed on a top surface of the first cover member 22a. The first MEMS element 21a can be a gyroscope, an accelerometer, an angular velocity meter, a magnetometer, a pressure sensor or an RF MEMS element. The first cover member 22a can be made of glass or silicon.

Referring to FIG. 2B, a carrier 20′ having a plurality of substrates 20 is provided. The carrier 20′ can be a wafer. Each of the substrates 20 has a first surface 20a and a second surface 20b opposite to the first surface 20a. A plurality of first conductive pads 201 and a plurality of second conductive pads 202 are disposed on the first surface 20a. The first MEMS element 21a is attached to the first surface 20a of one of the substrates 20 through the adhesive layer 23 thereof. The second surface 20b of the substrate 20 can have at least an alignment key 200 such as a recess that can be used by a double side aligner for alignment purposes during subsequent processes. The substrate 20 can be an ASIC chip. Referring to FIG. 2C, the first MEMS element 21a is electrically connected to the second conductive pads 202 through a plurality of second bonding wires 252.

Referring to FIG. 2D, the metal layer 24 is electrically connected to the first conductive pads 201 through a plurality of first bonding wires 251.

Referring to FIG. 2E, an encapsulant 26 is formed on the substrate 20 and encapsulating the first MEMS element 21a, the first cover member 22a, the first bonding wires 251 and the second bonding wires 252. The encapsulant 26 can be made of a thermosetting resin such as an epoxy resin, an epoxy molding compound (EMC), polyimide, or silicone.

Referring to FIG. 2F, the encapsulant 26 is partially removed from a top surface thereof. That is, an upper portion of the encapsulant 26 and top portions of the wire loops of the first bonding wires 251 are removed so as to separate the first bonding wires 251 into a plurality of first wire segments 251a and a plurality of second wire segments 251b. The first wire segments 251a have one ends exposed from the top surface of the encapsulant 26 and the other ends electrically connecting to the first conductive pads 201, respectively. The second wire segments 251b have one ends exposed from the top surface of the encapsulant 26 and the other ends electrically connecting to the metal layer 24. The encapsulant 26 can be partially removed by grinding, laser, plasma or chemical etching.

Referring to FIG. 20, a redistribution layer 27 is formed on the encapsulant 26 and electrically connected to the first wire segments 251a. The redistribution layer 27 can have a dielectric layer and a circuit layer stacked on each other. The layout of the redistribution layer 27 can be flexibly adjusted according to the electrical requirement. Further, an insulating protection layer 28 is formed on the redistribution layer 27 and at least an opening 280 is formed in the insulating protection layer 28 such that a portion of the redistribution layer 27 is exposed so as for a solder ball 29 to be mounted thereon. The solder ball 29 can be made of metal or an alloy and have a soldering or welding property. Preferably, the solder ball 29 is made of Sn/Pb, Sn/Ag/Cu or Au. Finally, a singulation process is performed.

### SECOND EMBODIMENT

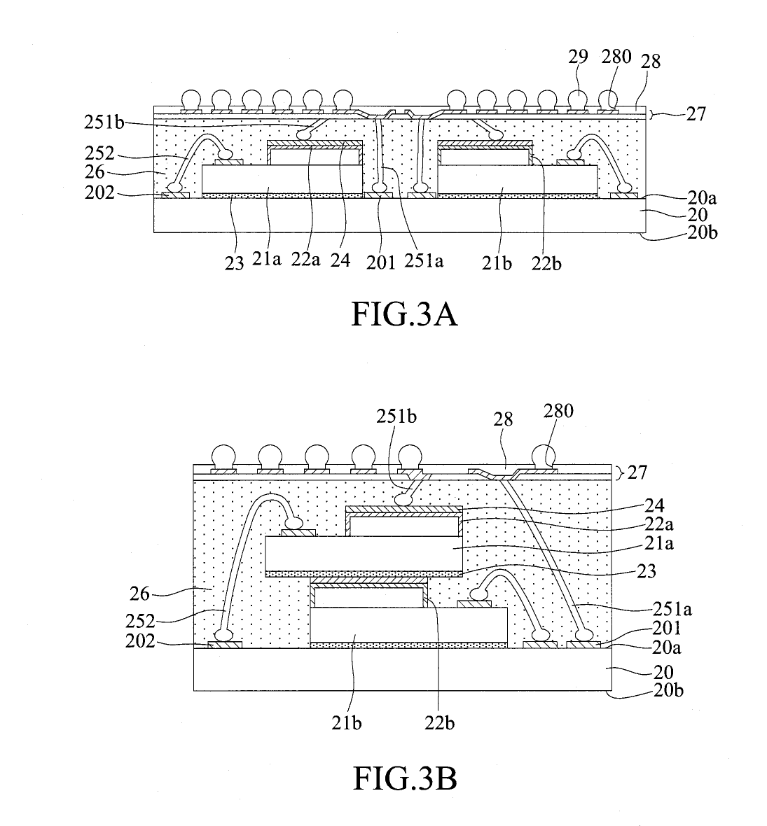

FIGS. 3A and 3B are schematic cross-sectional views showing a package structure having a MEMS element according to a second embodiment of the present invention. The second embodiment differs from the first embodiment is that the package structure of the second embodiment has a plurality of MEMS elements disposed therein so as to achieve integrated electrical functions. Referring to FIG. 3A, the MEMS elements can be disposed on the first surface 20a of the substrate 20 and adjacent to one another. Alternatively, the MEMS elements can be stacked on one another. Referring to FIG. 3B, a second MEMS element 2 lb having a second cover member 22b disposed thereon is disposed on substrate 20, and the first MEMS element 21a is disposed on and connected to the second cover member 22b of the second MEMS element 21b through a bottom surface thereof. But it should be noted that the present invention is not limited to the above-described configurations.

The present invention further provides a package structure, comprising: a substrate 20 having a first surface 20a and a second surface 20b opposite to the first surface 20a, a plurality of first conductive pads 201 and a plurality of second conductive pads 202 being disposed on the first surface 20a; at least a first MEMS element 21a disposed on the first surface 20a of the substrate 20; a first cover member 22a disposed on the first MEMS element 21a and having a metal layer 24 formed on a top surface thereof; a plurality of second bonding wires 252 electrically connected to the first MEMS element 21a and the second conductive pads 202; a plurality of first wire segments 251a, each having one end electrically connected to a corresponding one of the first conductive pads 201; a plurality of second wire segments 251b, each having one end electrically connected to the metal layer 24; and an encapsulant 26 formed on the substrate 20 and encapsulating the first MEMS element 21a, the first cover member 22a, the first wire segments 251a, the second wire segments 251b and the second bonding wires 252, wherein the other end of each of the first wire segments 251a and the second wire segments 251b is exposed from the encapsulant 26.

The package structure further has a redistribution layer 27 formed on the encapsulant 26 and electrically connected to the first wire segments 251a; and an insulating protection layer 28 formed on the redistribution layer 27 and having at least an opening 280 therein such that a portion of the redistribution layer 27 is exposed so as for a solder ball 29 to be mounted thereon.

In the above-described package structure, the second surface 20b of the substrate 20 has a plurality of alignment keys 200 such as recesses.

The package structure further has a second MEMS element 21b disposed between the first MEMS element 21a and the substrate 20. The second MEMS element 21b has a second cover member 22b disposed thereon for connecting a bottom surface of the first MEMS element 21a.

In the above-described package structure, an adhesive layer 23 is formed on the bottom surface of the first MEMS element 21a so as to attach the first MEMS element 21a to the first surface 20a of the substrate 20. The first MEMS element 21a can be a gyroscope, an accelerometer, an angular velocity meter, a magnetometer, a pressure sensor or an RF MEMS element.

Since singulated MEMS elements are used in the present invention, known good dies (KGD) can be selected so as to increase the yield of the package structure. Further, by forming alignment keys on a bottom surface of the substrate, a double side aligner can be conveniently used for alignment during the fabrication process. Furthermore, the present invention is applicable to the case in which the MEMS element is smaller in size than the substrate. In addition, a plurality of MEMS elements can be integrated in a same package structure so as to increase the overall functionality.

The above-described descriptions of the detailed embodiments are intended to illustrate the preferred implementation according to the present invention but are not intended to limit the scope of the present invention. Accordingly, all modifications and variations completed by those with ordinary skill in the art should fall within the scope of present invention defined by the appended claims.

What is claimed is:

1. A package structure, comprising:
a substrate having a first surface and a second surface opposite to the first surface, a plurality of first conductive pads and a plurality of second conductive pads disposed on the first surface;
a first MEMS element disposed on the first surface of the substrate;
a first cover member disposed on the first MEMS element and having a metal layer formed on a top surface thereof;
a plurality of bonding wires electrically connected to the first MEMS element and the second conductive pads;
a plurality of first wire segments, each having one end electrically connected to a corresponding one of the first conductive pads; and
an encapsulant formed on the substrate and encapsulating the first MEMS element, the first cover member, the first wire segments and the bonding wires, wherein the other end of each of the first wire segments is exposed from the encapsulant.

2. The package structure of claim 1, further comprising a plurality of second wire segments, each having one end electrically connected to the metal layer.

3. The package structure of claim 2, wherein the other end of each of the second wire segments is exposed from the encapsulant.

4. The package structure of claim 3, further comprising a redistribution layer formed on the encapsulant and electrically connecting the second wire segments.

5. The package structure of claim 1, wherein the substrate is a semiconductor chip.

6. The package structure of claim 5, wherein the semiconductor chip is an application specific integrated circuit (ASIC) chip.

7. The package structure of claim 1, further comprising a redistribution layer formed on the encapsulant and electrically connected the first wire segments.

8. The package structure of claim 1, wherein the second surface of the substrate has at least an alignment key.

9. The package structure of claim 8, wherein the alignment key is a recess.

10. The package structure of claim 1, further comprising a second MEMS element disposed between the first MEMS element and the substrate and having a second cover member disposed thereon and connected to a bottom surface of the first MEMS element.

11. The package structure of claim 1, wherein the first MEMS element is a gyroscope, an accelerometer, an angular velocity meter, a magnetometer, a pressure sensor or an RF MEMS element.

12. A fabrication method of a package structure, comprising the steps of:
providing a substrate having a first surface and a second surface opposite to the first surface, a plurality of first conductive pads and a plurality of second conductive pads disposed on the first surface;
disposing a first MEMS element on the first surface of the substrate, wherein the first MEMS element has a first cover member disposed thereon and a metal layer is formed on a top surface of the first cover member;
electrically connecting the metal layer and the first conductive pads through a plurality of first bonding wires, and electrically connecting the first MEMS element and the second conductive pads through a plurality of second bonding wires;
forming on the substrate an encapsulant encapsulating the first MEMS element, the first cover member, the first bonding wires and the second bonding wires; and
partially removing the encapsulant from a top surface thereof so as to separate the first bonding wires into a plurality of first wire segments with one ends electrically connecting to the first conductive pads and the other ends exposed from the encapsulant.

13. The fabrication method of claim 12, further comprising separating the first bonding wires into a plurality of second wire segments, each having one end electrically connected to the metal layer.

14. The fabrication method of claim 13, wherein the other end of each of the second wire segments is exposed from the encapsulant.

15. The fabrication method of claim 14, further comprising forming on the encapsulant a redistribution layer electrically connecting the second wire segments.

16. The fabrication method of claim 12, wherein the substrate is a semiconductor chip.

17. The fabrication method of claim 16, wherein the semiconductor chip is an ASIC chip.

18. The fabrication method of claim 12, further comprising performing a singulation process.

19. The fabrication method of claim 12, further comprising forming on the encapsulant a redistribution layer electrically connected to the first wire segments.

20. The fabrication method of claim 12, wherein the second surface of the substrate has at least an alignment key.

21. The fabrication method of claim 20, wherein the alignment key is a recess.

22. The fabrication method of claim 12, further comprising, prior to disposing the first MEMS element on the first surface of the substrate, disposing a second MEMS element on the first surface of the substrate, wherein the second MEMS element has a second cover member disposed thereon and connected to a bottom surface of the first MEMS element.

23. The fabrication method of claim 12, wherein the encapsulant is partially removed by grinding, laser, plasma or chemical etching.

24. The fabrication method of claim 12, wherein the first MEMS element is a gyroscope, an accelerometer, an angular velocity meter, a magnetometer, a pressure sensor or an RF MEMS element.
